(19) United States
(12) Patent Application Publication
(10) Pub. No.: US 2026/0339470 A1
(43) Pub. Date: Oct. 29, 2026

(54) DISPLAY DEVICE

(71) Applicant: LG Display Co., Ltd., Seoul (KR)

(72) Inventors: Hyangmyoung GWON, Seoul (KR); JiHyun JUNG, Seoul (KR); JaeGyun LEE, Seoul (KR); Ruda RHE, Seoul (KR)

(73) Assignee: LG Display Co., Ltd., Seoul (KR)

(21) Appl. No.: 19/641,248

(22) Filed: Apr. 7, 2026

(30) Foreign Application Priority Data
Apr. 28, 2025 (KR) 10-2025-0055731

(51) Int. Cl. G06F 3/044; H10K 59/131; H10K 59/40

(52) U.S. Cl. CPC G06F 3/0443; G06F 3/0446; H10K 59/131; H10K 59/40

(57) ABSTRACT

A display device can include a substrate having a display area in which a plurality of sub pixels are disposed and a non-display area around the display area and including a bending area and a pad area, a plurality of light emitting elements disposed in the plurality of sub pixels, and an encapsulation part disposed to cover the plurality of light emitting elements. The display device can further include a touch sensing unit having a plurality of bridge electrodes disposed on the encapsulation part and a plurality of touch electrodes disposed on or below the plurality of bridge electrodes, a plurality of pads disposed in the pad area, and a plurality of touch routing lines disposed in the non-display area and electrically connecting the plurality of touch electrodes and the plurality of pads.

### CROSS-REFERENCE TO RELATED APPLICATIONS

This application claims priority to Korean Patent Application No. 10-2025-0055731 filed on Apr. 28, 2025, in the Ministry of Intellectual Property of the Republic Korea, the entire disclosure of which is hereby expressly incorporated by reference.

### BACKGROUND

### Field

The present disclosure relates to a display device, and more particularly, to a display device capable of compensating for a resistance of a plurality of touch routing lines.

### Discussion of the Related Art

As the world enters the information age, the field of display devices that visually display electrical information signals is rapidly developing, and research is being conducted to develop performances such as thinning, weight reduction, and low power consumption for various display devices.

Representative display devices include a liquid crystal display (LCD), a field emission display (FED), an electro-wetting display (EWD), and an organic light emitting display (OLED).

In order to provide more various functions to the user, such a display device provides a function of recognizing a user's touch on the display panel and performing input processing based on the recognized touch.

A display device capable of touch recognition includes a plurality of touch electrodes disposed on or embedded in a display panel, and by driving the touch electrodes, it is possible to detect whether a user touches the display panel and touch coordinates.

### SUMMARY OF THE DISCLOSURE

An object to be achieved by the present disclosure is to provide a display device capable of compensating for resistance of a plurality of touch routing lines.

Another object to be achieved by the present disclosure is to provide a display device capable of reducing or minimizing a bezel area.

Still another object to be achieved by the present disclosure is to provide a display device which compensates for an RC (resistance-capacitance) deviation of a plurality of touch routing lines.

Objects of the present disclosure are not limited to the above-mentioned objects, and other objects, which are not mentioned above, can be clearly understood by those skilled in the art from the following descriptions.

According to an embodiment of the present disclosure, a display device includes a substrate including a display area in which a plurality of sub pixels are disposed and a non-display area disposed to surround the display area and including a bending area and a pad area, a plurality of light emitting elements disposed in the plurality of sub pixels, an encapsulation part disposed to cover the plurality of light emitting elements, a touch sensing unit including a plurality of bridge electrodes disposed on the encapsulation part and a plurality of touch electrodes disposed on or below the plurality of bridge electrodes, a plurality of pads disposed in the pad area, and a plurality of touch routing lines disposed in the non-display area and electrically connecting the plurality of touch electrodes and the plurality of pads, wherein the plurality of touch routing lines includes a plurality of first layers disposed on the same layer as the plurality of bridge electrodes, and a plurality of second layers disposed on the same layer as the plurality of touch electrodes and alternately with the plurality of first layers.

A display device according to another example embodiment of the present disclosure includes a substrate including a display area in which a plurality of sub pixels are disposed and a non-display area disposed to surround the display area and including a bending area and a pad area, a plurality of light emitting elements disposed in the plurality of sub pixels, an encapsulation part disposed to cover the plurality of light emitting elements, a touch sensing unit including a plurality of bridge electrodes disposed on the encapsulation part, a touch interlayer insulating layer covering the plurality of bridge electrodes, a plurality of first touch electrodes disposed on the touch interlayer insulating layer and disposed in a first direction, and a plurality of second touch electrodes disposed in a second direction intersecting the first direction, a plurality of pads disposed in the pad area, a plurality of first touch routing lines electrically connecting the plurality of first touch electrodes and the plurality of pads in the non-display area, and a plurality of second touch routing lines electrically connecting the plurality of second touch electrodes and the plurality of pads, the plurality of second touch routing lines includes a first layer disposed on the same layer as the bridge electrode and a second layer disposed on the same layer as the plurality of first touch electrodes and the plurality of second touch electrodes, and the first layer and the second layer are disposed alternate with each other.

Other detailed matters of the embodiments of the present disclosure are included in the detailed description and the drawings.

In the display device according to aspects of the present disclosure, a single alternating line which alternately connects a plurality of first layers disposed on the same layer as a plurality of bridge electrodes and a plurality of second layers disposed on the same layer as a plurality of touch electrodes is applied as a plurality of touch routing lines to reduce the area of the touch routing lines disposed in the bezel area, thereby minimizing the bezel area of the display device.

In the display device according to aspects of the present disclosure, the resistance of the touch sensing unit can be reduced by disposing the plurality of auxiliary electrodes in the display area and electrically connecting the plurality of auxiliary electrodes to the plurality of touch electrodes, thereby compensating for the resistance of the plurality of touch routing lines in the display area.

In the display device according to aspects of the present disclosure, the number of connections between the plurality of touch electrodes and the plurality of auxiliary electrodes varies depending on the length or position of the plurality of touch routing lines to improve the resistance deviation and RC deviation of the plurality of touch routing lines.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic perspective view of a display device according to an example embodiment of the present disclosure.

FIG. 2 is a plan view schematically illustrating a structure of a touch sensing unit according to an example embodiment of the present disclosure.

FIG. 3 is an enlarged schematic plan view of an area A of FIG. 2 according to an example of the present disclosure.

FIG. 4 is a cross-sectional view taken along line I-I' in FIG. 3 according to an example of the present disclosure.

FIG. 5 is a cross-sectional view taken along line II-II' in FIG. 3 according to an example of the present disclosure.

FIG. 6 is a plan view schematically illustrating a structure of a touch sensing unit according to another embodiment of the present disclosure.

FIG. 7A is a cross-sectional view taken along the line III-III' of FIG. 6 according to an example of the present disclosure.

FIG. 7B is a cross-sectional view taken along line IV-IV' in FIG. 6 according to an example of the present disclosure.

FIG. 7C is a cross-sectional view taken along line V-V' in FIG. 6 according to an example of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed therebetween or it can be disposed directly on the other element or layer.

Although the terms such as “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” fully encompasses all the meanings and coverages of the term “may.”

Hereinafter, various embodiments of the present disclosure will be described with reference to the drawings. All the components of each display device/apparatus according to all embodiments of the present disclosure are operatively coupled and configured.

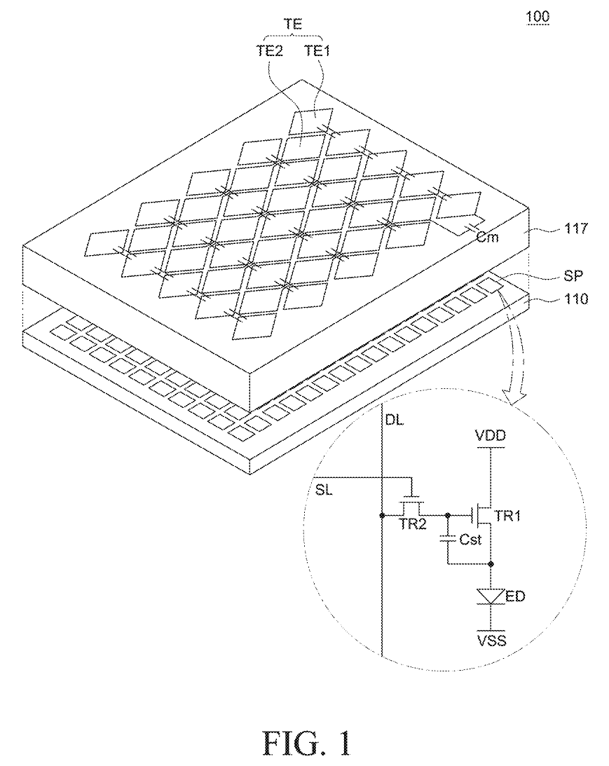

FIG. 1 is a schematic perspective view of a display device according to an example embodiment of the present disclosure.

Referring to FIG. 1, a display device 100 according to an example embodiment of the present disclosure includes a plurality of sub pixels SP arranged in a matrix in a display area of a substrate 110, an encapsulation part 117 disposed on the plurality of sub pixels SP, and a plurality of touch electrodes TE disposed on the encapsulation part 117.

The substrate 110 is a component for supporting various components included in the display device 100 and can be made of an insulating material. The substrate 110 can be made of a transparent insulating material, for example, glass or resin. In addition, the substrate 110 can include polymer or plastic, or can be made of a material having flexibility.

A plurality of gate lines and a plurality of data lines are disposed to cross each other on the substrate 110. A plurality of sub pixels SP are defined at intersections of the plurality of gate lines and the plurality of data lines. An area in which the plurality of sub pixels SP implementing an image is disposed can be expressed as a display area, and an area which is disposed outside the display area and in which the plurality of sub pixels SP is not disposed can be expressed as a non-display area.

The display area is an area in which an image is displayed in the display device 100. In the display area, a plurality of sub pixels SP constituting a plurality of pixels and a pixel driving circuit for driving the plurality of sub pixels SP can be disposed. The plurality of sub pixels SP is a minimum unit constituting the display area, and n sub pixels SP can form one pixel. Transistors for driving a plurality of light emitting elements are disposed in each of the plurality of sub pixels SP so that the plurality of sub pixels SP can independently emit light. For example, the plurality of sub pixels SP can include a red sub pixel, a green sub pixel, and a blue sub pixel, but is not limited thereto and can include a red sub pixel, a green sub pixel, a blue sub pixel, and a white sub pixel.

The non-display area is an area in which no image is displayed and can be defined as an area extending from the display area. In the non-display area, a link line for transmitting a signal to the plurality of sub pixels SP of the display area, various driving units such as a pad electrode, a gate driving unit, and a data driving unit, and COP (chip on plastic) and FPCB (flexible printed circuit board) in which driving circuits are disposed can be disposed. Further, a gate driving circuit referred to as a gate in panel (GIP) can be disposed in the non-display area.

In the display device 100 according to the example embodiment of the present disclosure, the display device 100 having a plurality of touch electrodes TE senses the presence of a touch and a touch position by sensing a change amount of mutual capacitance (Cm; touch sensor) caused by a user's touch through the plurality of touch electrodes TE during the touch period.

Each of the plurality of sub pixels SP disposed in the display area of the substrate includes a pixel driving circuit and a light emitting element connected to the pixel driving circuit.

The pixel driving circuit can include a first transistor TR1, a second transistor TR2, a capacitor Cst, and a light emitting element ED.

For example, the first transistor TR1 can operate such that a driving current flows between the high potential power line VDD and the low potential power line VSS according to the data voltage stored in the capacitor Cst. In addition, the light emitting element ED can operate to emit light according to the driving current formed by the first transistor TR1. For example, the first transistor TR1 can be referred to as a driving transistor. Further, for example, the second transistor TR2 can perform a switching operation in response to a scan signal supplied through the scan line SL so that a data signal supplied through the data line DL is stored as a data voltage in the capacitor Cst. For example, the second transistor TR2 can be referred to as a switching transistor.

The sub pixel illustrated in FIG. 1 is configured by a 2T(transistor)1C(capacitor) structure including a first transistor TR1, a second transistor TR2, a capacitor Cst, and a light emitting element ED. When a compensation circuit is added, the sub pixel can be configured in various forms, such as 3T1C, 4T2C, 5T2C, 6T1C, 6T2C, 7T1C, and 7T2C.

Since the light emitting element ED in each sub pixel SP is vulnerable to external moisture or oxygen, the encapsulation part 117 for preventing external moisture or oxygen from penetrating into the light emitting element ED can be disposed on the substrate 110. The encapsulation part 117 can be disposed to cover the light emitting elements ED.

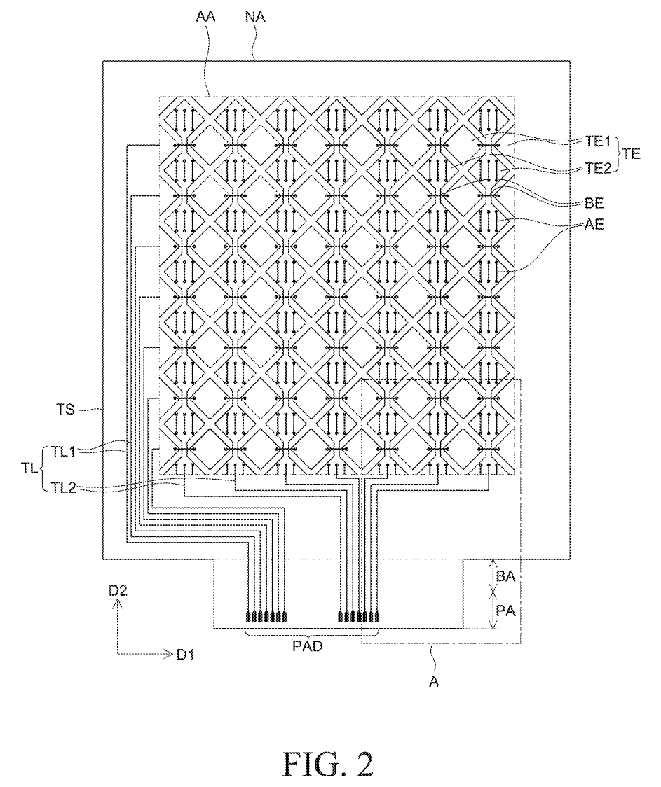

FIG. 2 is a plan view schematically illustrating a structure of a touch sensing unit TS which can be applied to a display device according to an embodiment of the present disclosure.

Referring to FIG. 2, the touch sensing unit TS senses a user's touch input.

The display device 100 can further include a touch driver configured to supply a touch driving signal to the touch sensing unit TS and detect a touch sensing signal from the touch sensing unit TS.

The touch driver determines whether the user touches and a touch position. For example, when the user touches a partial area of the touch sensing unit TS, the touch driving unit senses a touch signal to determine whether the user touches the touch sensing unit TS and a touch position.

For example, the touch driver can supply a touch driving signal to each touch sensing unit TS. The touch driver can receive a touch sensing signal from the touch sensing unit TS. The touch driving unit can detect a touch in the touch sensing unit TS through the touch sensing signal.

The touch sensing unit TS includes a plurality of first touch electrodes TE1, a plurality of second touch electrodes TE2, a plurality of bridge electrodes BE, a plurality of touch routing lines TL, and a plurality of touch pads PAD.

The plurality of first touch electrodes TE1 can be touch driving electrodes, and the plurality of second touch electrodes TE2 can be touch sensing electrodes. The plurality of first touch electrodes TE1 extends in the first direction D1 and is connected by the bridge electrode BE to form a plurality of electrode rows, and the plurality of second touch electrodes TE2 is connected in the second direction D2 intersecting the first direction D1 to form a plurality of electrode columns.

The plurality of first touch electrodes TE1 and the plurality of second touch electrodes TE2 can be disposed on the same layer. However, in an area where the plurality of first touch electrodes TE1 and the plurality of second touch electrodes TE2 intersect, the plurality of first touch electrodes TE1 can be disposed to be separated, and the plurality of separated first touch electrodes TE1 can be connected by the bridge electrode BE.

In this case, the plurality of first touch electrodes TE1, the plurality of second touch electrodes TE2, and the plurality of bridge electrodes BE are disposed in an area corresponding to the display area AA of the substrate 110.

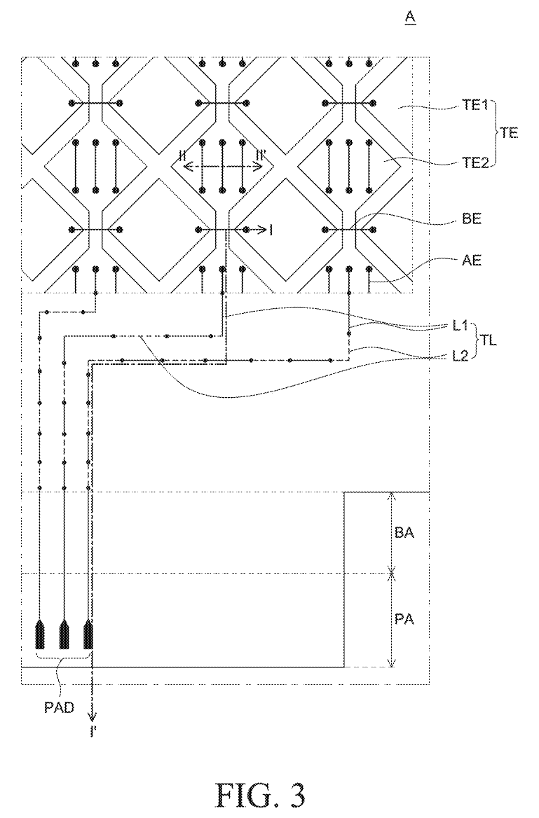

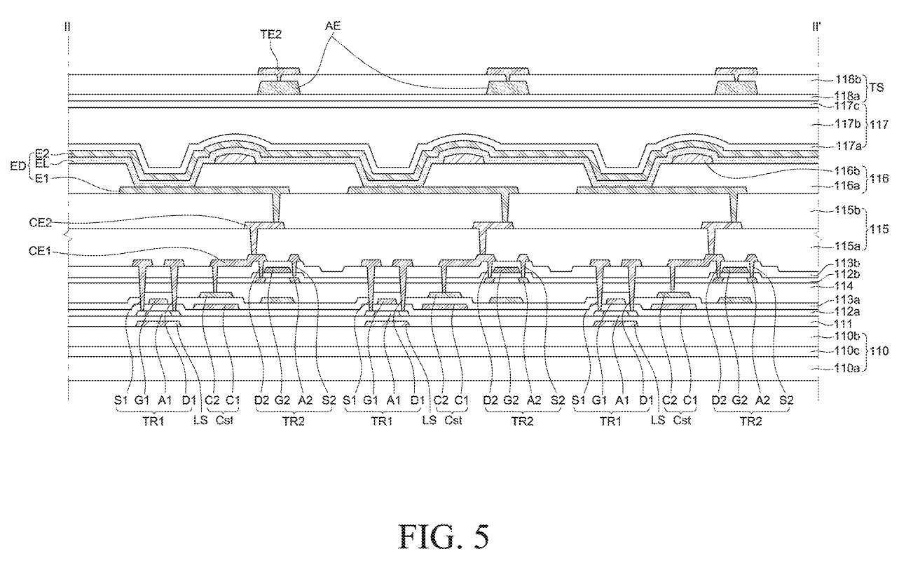

The display device 100 according to the example embodiment of the present disclosure can include a plurality of auxiliary electrodes AE disposed on the same layer as the plurality of bridge electrodes BE in the display area AA, is disposed in the second direction D2 and disposed to overlap the plurality of touch electrodes TE. The plurality of touch electrodes TE can be disposed on or below the plurality of bridge electrodes BE. For example, the plurality of auxiliary electrodes AE can be disposed to overlap the plurality of second touch electrodes TE2 among the plurality of touch electrodes TE. The relationship between the plurality of touch electrodes TE and the plurality of auxiliary electrodes AE will be described later with reference to FIGS. 3 and 5.

The outer shapes of the plurality of first touch electrodes TE1 and the plurality of second touch electrodes TE2 can correspond to a specific shape. For example, as illustrated in FIG. 2, outer shapes of the plurality of first touch electrodes TE1 and the plurality of second touch electrodes TE2 can have a mesh pattern including a plurality of rhombic shapes. For example, one mesh pattern of the plurality of touch electrodes TE can be disposed in one sub pixel, but is not limited thereto.

The plurality of first touch electrodes TE1 and the plurality of second touch electrodes TE2 can be formed of a metal including at least any one of titanium (Ti), aluminum (Al), molybdenum (Mo), molybdenum titanium (Moti), copper (Cu), and tantalum (Ta), and can be formed of a transparent conductive material such as indium tin oxide (ITO), indium zinc oxide (IZO), but is not limited thereto. Light emitted from the display device 100 can pass through the plurality of first touch electrodes TE1 and the plurality of second touch electrodes TE2 made of a transparent conductive material and be emitted to the outside. However, the present disclosure is not limited thereto. Light emitted from the display device 100 can be emitted to the outside through a plurality of openings included in the plurality of first touch electrodes TE1 and the plurality of second touch electrodes TE2.

A plurality of touch routing lines TL and a plurality of touch pads PAD are disposed in an area corresponding to the non-display area NA. The non-display area NA can surround the display area AA and include a bending area BA and a pad area PA in which the plurality of touch pads PAD are disposed.

Each of the plurality of touch routing lines TL electrically connects each of the plurality of touch electrodes TE disposed in the display area AA to the touch pad PAD in the non-display area NA. For example, a touch driving signal can be applied to the plurality of first touch electrodes TE1 through the plurality of first touch routing lines TL1 connected to the plurality of first touch electrodes TE1 and a touch sensing signal can be transmitted to the plurality of second touch electrodes TE2 through the plurality of second touch routing lines TL2 connected to the plurality of second touch electrodes TE2. The plurality of first touch routing lines TL1 can electrically connect the plurality of first touch electrodes TE1 and the plurality of pads PAD in the non-display area NA, and the plurality of second touch routing lines TL2 can electrically connect the plurality of second touch electrodes TE2 and the plurality of pads PAD.

The plurality of touch routing lines TL can be formed of a low-resistance metal material, or can be formed of a transparent conductive material such as ITO or IZO, but is not limited thereto. For example, when the plurality of touch routing lines TL is made of a low-resistance metal material, the resistance is lowered and the RC (resistance-capacitance) delay can be lowered.

The plurality of touch pads PAD can be electrically connected to an external circuit such as the plurality of touch routing lines TL and the touch driver to receive a touch signal from the external circuit or transmit a touch sensing signal to the external circuit.

Hereinafter, the plurality of touch routing lines TL and the display area AA of the display device 100 will be described in more detail with reference to FIGS. 3-5.

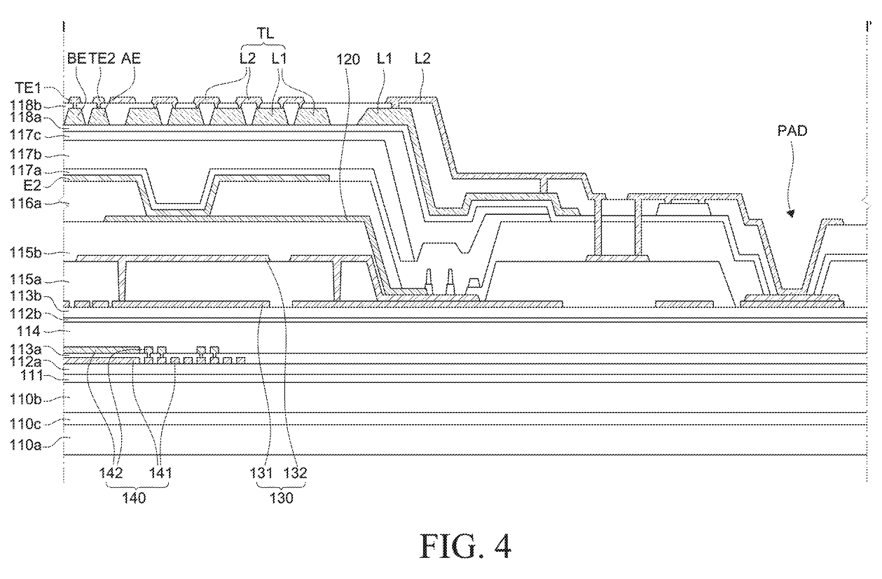

FIG. 3 is an enlarged schematic plan view of an area A of FIG. 2. FIG. 4 is a cross-sectional view taken along line I-I' in FIG. 3. FIG. 5 is a cross-sectional view taken along line II-II' in FIG. 3. Particularly, FIG. 3 is an enlarged plan view of an area where a plurality of first touch electrodes TE1 and a plurality of second touch electrodes TE2 intersect and an area where a plurality of touch routing lines TL is disposed. In FIG. 4, the I-I' line indicates that a plurality of routing lines are cut, but for the convenience of illustration, the I-I' line is displayed next to the plurality of touch routing lines.

First, referring to FIGS. 3-5, the substrate 110 is a component for supporting various components included in the display device 100 and can be made of an insulating material. The substrate 110 can include a first substrate 110a, a second substrate 110b, and an interlayer insulating layer 110c. The interlayer insulating layer 110c can be disposed between the first substrate 110a and the second substrate 110b. As described above, the substrate 110 is configured by the first substrate 110a, the second substrate 110b, and the interlayer insulating layer 110c to suppress moisture permeation. For example, the first substrate 110a and the second substrate 110b can be polyimide (PI) substrates, and the interlayer insulating layer 110c can be formed of a single layer of silicon nitride (SiNx) or silicon oxide (SiOx) or a multi-layer thereof.

A light shielding layer LS can be disposed on the substrate 110.

The first buffer layer 111 can be disposed on the substrate 110 while covering the light shielding layer LS. Specifically, the first buffer layer 111 can be disposed on the substrate 110 while covering the light shielding layer LS.

The first buffer layer 111 can delay diffusion of moisture or oxygen permeating the substrate 110 and can include at least one of silicon nitride (SiNx) and silicon oxide (SiOx).

In addition, the first buffer layer 111 can protect the first active layer A1 and block various types of defects introduced from the substrate 110.

The first thin film transistor TR1 can be disposed on the first buffer layer 111. The first thin film transistor TR1 can include a first active layer A1, a first gate electrode G1, a first source electrode S1, and a first drain electrode D1. Here, depending on the design of the pixel circuit, the first source electrode S1 can be the first drain electrode, and the first drain electrode D1 can be the first source electrode.

The first active layer A1 can be disposed on the first buffer layer 111 so as to overlap the light shielding layer LS. The first active layer A1 can include amorphous silicon or polycrystalline silicon. For example, the first active layer A1 can include low-temperature polysilicon (LTPS). For example, the polycrystalline silicon material has a high mobility (100 cm2/Vs or more), low energy power consumption, and excellent reliability. Therefore, the polycrystalline silicon material can be applied to a gate driver for a driving element which drives thin film transistors for a display element and/or a multiplexer (MUX) and applied as an active layer A1 of a driving thin film transistor in the display device 100 according to an example embodiment of the present disclosure, but is not limited thereto. For example, it can be applied to the active layer A2 of the switching thin film transistor according to the characteristics of the display device 100. An amorphous silicon (a-Si) material is deposited on the first buffer layer 111, a polysilicon is formed by performing a dehydrogenation process and a crystallization process, and the polysilicon is patterned to form the first active layer A1. Here, the first active layer A1 can include a first channel area in which a channel is formed when the first thin film transistor TR1 is driven, and a first source area and a first drain area on both sides of the first channel area. The first source area refers to a portion of the first active layer A1 connected to the first source electrode S1, and the first drain area refers to a portion of the first active layer A1 connected to the first drain electrode D1. For example, the first source area and the first drain area can be configured by ion-doping (impurity doping) of the first active layer A1. The first source area and the first drain area can be generated by doping ions into the polysilicon material, and the first channel area can mean a portion in which the ions are not doped, but the polysilicon material remains.

The first gate insulating layer 112a can be disposed on the first active layer A1. The first gate insulating layer 112a can be configured by a single layer of silicon nitride (SiNx) or silicon oxide (SiOx) or a multi-layer thereof. In the first gate insulating layer 112a, a contact hole through which the first source electrode S1 and the first drain electrode D1 of the first thin film transistor TR1 are connected to the first source area and the first drain area of the first active layer A1 of the first thin film transistor TR1, respectively, can be formed.

The first gate electrode G1 of the first thin film transistor TR1 and the first capacitor electrode C1 of the storage capacitor Cst can be disposed on the first gate insulating layer 112a.

In this case, the first gate electrode G1 and the first capacitor electrode C1 can be formed of a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof. The first gate electrode G1 can be formed on the first gate insulating layer 112a so as to overlap the first channel area of the first active layer A1 of the first thin film transistor TR1.

The first capacitor electrode C1 can be omitted based on the driving characteristics of the display device 100 and the structure and type of the thin film transistor. The first gate electrode G1 and the first capacitor electrode C1 can be formed by the same process. Further, the first gate electrode G1 and the first capacitor electrode C1 can be formed of the same material and can be formed on the same layer.

The first interlayer insulating layer 113a can be disposed on the first gate insulating layer 112a, the first gate electrode G1, and the first capacitor electrode C1. The first interlayer insulating layer 113a can be configured by a single layer of silicon nitride (SiNx) or silicon oxide (SiOx) or a multi-layer thereof. Further, a contact hole for exposing the first source area and the first drain area of the first active layer A1 of the first thin film transistor TR1 can be formed in the first interlayer insulating layer 113a.

The second capacitor electrode C2 of the storage capacitor Cst can be disposed on the first interlayer insulating layer 113a. The second capacitor electrode C2 can be formed by a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof. The second capacitor electrode C2 can be formed on the first interlayer insulating layer 113a so as to overlap the first capacitor electrode C1. Further, the second capacitor electrode C2 can be formed of the same material as the first capacitor electrode C1. The second capacitor electrode C2 can be omitted based on the driving characteristics of the display device 100 and the structure and type of the thin film transistor.

Meanwhile, when the gate driver disposed in the non-display area NA of the substrate 110 is applied in a gate-in-panel (GIP) manner, the gate driving circuit 140 including a plurality of transistors can be formed in the non-display area NA.

The gate driving circuit 140 can include the same material on the same layer as components of the first transistor TR1 and/or the second transistor TR2. For example, the gate driving circuit 140 can include a first gate driving circuit 141 formed of the same material on the same layer as the first gate electrode G1 of the first thin film transistor TR1 and the first capacitor electrode C1 of the storage capacitor Cst, and a second gate driving circuit 142 formed of the same material on the same layer as the second capacitor electrode C2 of the storage capacitor Cst.

The second buffer layer 114 can be disposed on the first interlayer insulating layer 113a, the second capacitor electrode C2, and the second gate driving circuit 142. The second buffer layer 114 can be configured by a single layer of silicon nitride (SiNx) or silicon oxide (SiOx) or a multi-layer thereof. A contact hole for exposing the first source area and the first drain area of the first active layer A1 of the first thin film transistor TR1 can be formed in the second buffer layer 114. Further, a contact hole for exposing the second capacitor electrode C2 of the storage capacitor Cst can be formed in the second buffer layer 114.

The second buffer layer 114 can be formed by a multi-layer, but is not limited thereto.

A second active layer A2 of the second thin film transistor TR2 can be disposed on the second buffer layer 114. Here, the second thin film transistor TR2 can include a second active layer A2, a second gate insulating layer 112b, a second gate electrode G2, a second source electrode S2, and a second drain electrode D2. Here, depending on the design of the pixel circuit, the second source electrode S2 can be a drain electrode, and the second drain electrode D2 can be a source electrode.

Further, the second active layer A2 can include a second channel area in which a channel is formed when the second thin film transistor TR2 is driven, and a second source area and a second drain area on both sides of the second channel area. The second source area can refer to a portion of the second active layer A2 connected to the second source electrode S2, and the second drain area can refer to a portion of the second active layer A2 connected to the second drain electrode D2.

The second active layer A2 can be formed of an oxide semiconductor. Since the oxide semiconductor material has a larger band gap than the silicon material, electrons cannot cross the band gap in an off state, and accordingly, the off-current is low. Therefore, the thin film transistor including the active layer made of the oxide semiconductor can be suitable for a switching thin film transistor which maintains a short on-time and a long off-time, but is not limited thereto. Depending on the characteristics of the display device 100, it can be applied as a driving thin film transistor. Since the off-current is small, the size of the auxiliary capacity can be reduced, and thus, it is suitable for a high-resolution display element. For example, the second active layer A2 can be made of a metal oxide and for example, can be made of various metal oxides such as indium-gallium-zinc-oxide (IGZO). Here, it is assumed and described that the second active layer A2 of the second thin film transistor TR2 is formed of IGZO among various metal oxides, but it is not limited thereto and can be formed of other metal oxides such as indium-zinc-oxide (IZO), indium-gallium-tin-oxide (IGTO), or indium-gallium-oxide (IGO), rather than IGZO.

The second active layer A2 can be formed by depositing a metal oxide on the second buffer layer 114, performing a heat treatment for stabilization, and then patterning the metal oxide.

The second gate insulating layer 112b can be disposed on the entire substrate 110 including the second active layer A2. For example, the second gate insulating layer 112b can be configured by a single layer of silicon nitride (SiNx) or silicon oxide (SiOx) or a multi-layer thereof.

The second gate electrode G2 can be disposed on the second gate insulating layer 112b.

The second gate electrode G2 can be formed of a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof.

For example, a metal material is formed on the second gate insulating layer 112b, a photoresist pattern is formed on the metal material, and then the metal material is wet-etched using the photoresist pattern as a mask to form the second gate electrode G2. A wet etchant for etching a metal material can be a material which selectively etches molybdenum (Mo), copper (Cu), titanium (Ti), aluminum (Al), chromium (Cr), gold (Au), nickel (Ni), neodymium (Nd), or an alloy thereof, and does not etch an insulating material.

The second interlayer insulating layer 113b can be disposed on the second gate insulating layer 112b and the second gate electrode G2. A contact hole for exposing the first active layer A1 of the first thin film transistor TR1 and the second active layer A2 of the second thin film transistor TR2 can be formed in the second interlayer insulating layer 113b. For example, a contact hole for exposing the first source area and the first drain area of the first active layer A1 of the first thin film transistor TR1 can be formed in the second interlayer insulating layer 113b. A contact hole for exposing the second source area and the second drain area of the second active layer A2 of the second thin film transistor TR2 can be formed in the second interlayer insulating layer 113b.

The second interlayer insulating layer 113b can be configured by a single layer of silicon nitride (SiNx) or silicon oxide (SiOx) or a multi-layer thereof.

The first connection electrode CE1, the first source electrode S1 and the first drain electrode D1 of the first thin film transistor TR1 and the second source electrode S2 and the second drain electrode D2 of the second thin film transistor TR2 can be disposed on the second interlayer insulating layer 113b.

The first connection electrode CE1 can be electrically connected to the second drain electrode D2 of the second thin film transistor TR2. Further, the first connection electrode CE1 can be electrically connected to the second capacitor electrode C2 of the storage capacitor Cst through the contact holes formed in the second buffer layer 114 and the second interlayer insulating layer 113b. For example, the first connection electrode CE1 can serve to electrically connect the second capacitor electrode C2 of the storage capacitor Cst and the second drain electrode D2 of the second thin film transistor TR2.

Here, the first source electrode S1 and the first drain electrode D1 of the first thin film transistor TR1 can be connected to the first active layer A1 of the first thin film transistor TR1 through contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 can be connected to the second active layer A2 through a contact hole formed in the second interlayer insulating layer 112b.

The first connection electrode CE1, the first source electrode S1 and the first drain electrode D1 of the first thin film transistor TR1, and the second source electrode S2 and the second drain electrode D2 of the second thin film transistor TR2 can be formed of the same material by the same process.

For example, the first connection electrode CE1, the first source electrode S1 and the first drain electrode D1 of the first thin film transistor TR1, and the second source electrode S2 and the second drain electrode D2 of the second thin film transistor TR2 can be formed of a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof. For example, the first connection electrode CE1, the first source electrode S1 and the first drain electrode D1 of the first thin film transistor TR1, and the second source electrode S2 and the second drain electrode D2 of the second thin film transistor TR2 can have a three-layer structure of titanium (Ti)/aluminum (Al)/titanium (Ti), but are not limited thereto.

The first connection electrode CE1 can be integrally connected to the second drain electrode D2 of the second thin film transistor TR2, but is not limited thereto.

The first planarization layer 115a can be disposed above the first connection electrode CE1, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a can be an organic film for planarizing and protecting upper portions of the first thin film transistor TR1 and the second thin film transistor TR2. For example, the first planarization layer 115a can be formed of an organic material such as acryl resin, epoxy resin, phenolic resin, polyamide resin, or polyimide resin.

The second connection electrode CE2 can be disposed on the first planarization layer 115a. The second connection electrode CE2 can be connected to the second drain electrode D2 of the second thin film transistor TR2 through the contact hole of the first planarization layer 115a. The second connection electrode CE2 can serve to electrically connect the second thin film transistor TR2 and the anode E1. Further, the second connection electrode CE2 can be formed of a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof. The second connection electrode CE2 can be formed of the same material as the second source electrode S2 and the second drain electrode D2 of the second thin film transistor TR2.

The second planarization layer 115b can be disposed on the second connection electrode CE2 and the first planarization layer 115a. For example, the second planarization layer 115b can be formed of an organic material such as acryl resin, epoxy resin, phenolic resin, polyamide resin, or polyimide resin.

The light emitting element ED can be disposed on the second planarization layer 115b.

The anode E1 can be disposed on the second planarization layer 115b. In this case, the anode E1 can be electrically connected to the second connection electrode CE2 through a contact hole provided in the second planarization layer 115b. The anode E1 can be formed of a metallic material.

When the display device 100 is a top emission type in which light emitted from the light emitting element ED is emitted above the substrate 110 on which the light emitting element ED is disposed, the anode E1 can further include a transparent conductive layer and a reflective layer on the transparent conductive layer. The transparent conductive layer can be made of a transparent conductive oxide such as ITO or IZO, and the reflective layer can be made of, for example, silver (Ag), aluminum (Al), gold (Au), molybdenum (Mo), tungsten (W), chromium (Cr), or an alloy thereof.

The bank 116a can be disposed while covering the anode E1. A portion of the bank 116a corresponding to the emission area of the sub pixel can be opened. A part of the anode E1 can be exposed through the open part of the bank 116a (hereinafter, referred to as an open area). In this case, the bank 116a can be made of an inorganic insulating material, such as silicon nitride (SiNx) or silicon oxide (SiOx), or an organic insulating material, such as benzocyclobutene-based resin, acrylic-based resin, or imide-based resin, but is not limited thereto. A spacer 116b can be further disposed on the bank 116a.

The emission layer EL can be disposed in the open area of the bank 116a and in the vicinity of the open area of the bank. Accordingly, the emission layer EL can be disposed on the anode E1 exposed through the open area of the bank 116a.

The emission layer EL can include a plurality of organic layers. For example, the emission layer EL serves to emit light and can include a hole injection layer (HIL), a hole transport layer (HTL), an emission layer, an electron transport layer (ETL), and an electron injection layer (EIL). However, some components can be omitted depending on the structure or characteristics of the display device. Here, as the emission layer EL, an electroluminescent layer and an inorganic emission layer can be applied.

The cathode E2 can be disposed on the emission layer EL. The cathode E2 serves to supply electrons to the emission layer EL. Since the cathode E2 needs to supply electrons, the cathode E2 can be made of a metal material such as magnesium (Mg) or silver-magnesium, which are conductive materials having a low work function, but is not limited thereto. For example, when the display device 100 is a top emission type, the cathode E2 can include transparent conductive oxide such as indium tin oxide (ITO), indium zinc oxide (IZO), indium tin zinc oxide (ITZO), zinc oxide (ZnO), and tin oxide (TO).

The cathode E2 can be electrically connected to the connection line 120 and the common line 130. The common line 130 supplies a common voltage VSS to the connection line 120 and the connection line 120 is connected to the common line 130 and the cathode E2 to supply a common voltage to the cathode E2.

For example, the connection line 120 can be made of the same material on the same layer as the anode E1.

The connection line 120 can be connected by forming a contact hole in the bank 116a to electrically connect to the cathode E2.

The common line 130 can include a first common line 131 formed of the same material on the same layer as the first connection electrode CE1 and a second common line 132 formed of the same material on the same layer as the second connection electrode CE2. For example, the common line 130 can be formed by stacking a first common line 131 and a second common line 132.

The connection line 120 and the common line 130 can be in contact by forming contact holes in the first planarization layer 115a and the second planarization layer 115b.

The encapsulation part 117 can be positioned on the light emitting element ED described above.

The encapsulation part 117 can have a single-layered structure or a multi-layered structure. For example, the encapsulation part 117 can include a first encapsulation layer 117a, a second encapsulation layer 117b, and a third encapsulation layer 117c.

In this case, the first encapsulation layer 117a and the third encapsulation layer 117c can be configured by inorganic layers, and the second encapsulation layer 117b can be configured by an organic layer. Among the first encapsulation layer 117a, the second encapsulation layer 117b, and the third encapsulation layer 117c, the second encapsulation layer 117b is thickest and can serve as a planarization layer.

The first encapsulation layer 117a is disposed on the cathode E2 and can be disposed to be most adjacent to the light emitting element ED. The first encapsulation layer 117a can be formed of an inorganic insulating material on which low-temperature deposition can be performed. For example, the first encapsulation layer 117a can be made of silicon nitride (SiNx), silicon oxide (SiOx), silicon oxynitride (SiON), or aluminum oxide (Al₂O₃). Since the first encapsulation layer 117a is deposited in a low temperature atmosphere, it is possible to prevent damage to the emission layer EL including an organic material vulnerable to a high temperature atmosphere during the deposition process.

The second encapsulation layer 117b can be formed to have a smaller area than that of the first encapsulation layer 117a. In this case, the second encapsulation layer 117b can be formed to expose both ends of the first encapsulation layer 117a. The second encapsulation layer 117b can serve as a buffer to alleviate stress between layers due to bending of the flexible display device and to enhance planarization performance.

For example, the second encapsulation layer 117b can be made of an organic insulating material such as acrylic resin, epoxy resin, polyimide, polyethylene, or silicon oxycarbon (SiOC). For example, the second encapsulation layer 117b can be formed by an inkjet method, but is not limited thereto.

The third encapsulation layer 117c can be formed above the substrate 110 on which the second encapsulation layer 117b is formed so as to cover upper surfaces and side surfaces of the second encapsulation layer 117b and the first encapsulation layer 117a. In this case, the third encapsulation layer 117c can minimize or block the permeation of external moisture or oxygen into the first encapsulation layer 117a and the second encapsulation layer 117b. For example, the third encapsulation layer 117c can be made of an inorganic insulating material such as silicon nitride (SiNx), silicon oxide (SiOx), silicon oxynitride (SiON), or aluminum oxide (Al₂O₃).

The touch sensing unit TS can be disposed on the third encapsulation layer 117c. Specifically, the touch sensing unit TS can include a touch buffer layer 118a disposed on the third encapsulation layer 117c, a plurality of bridge electrodes BE disposed on the touch buffer layer 118a, a touch interlayer insulating layer 118b disposed on the plurality of bridge electrodes BE, a plurality of touch electrodes TE disposed on the touch interlayer insulating layer 118b and including a plurality of first touch electrodes TE1 and a plurality of second touch electrodes TE2, and a plurality of touch routing lines TL (for example, the above-described second touch routing lines TL2) disposed in the non-display area NA and including a plurality of first layers L1 and a plurality of second layers L2.

The touch buffer layer 118a can block a liquid chemical such as a developer or an etchant used in the manufacturing process of the plurality of touch electrodes TE formed on the touch buffer layer 118a or external moisture or foreign substances from penetrating into the light emitting element ED. For example, the touch buffer layer 118a can be configured by a single layer of silicon nitride (SiNx) or silicon oxide (SiOx) or a multi-layer thereof.

The touch buffer layer 118a can be formed to extend to the non-display area NA as well as the display area AA.

A plurality of bridge electrodes BE and a plurality of first layers L1 of the plurality of touch routing lines TL are disposed on the touch buffer layer 118a. The plurality of bridge electrodes BE is disposed in the display area AA, and electrically connects the plurality of first touch electrodes TE1 on the touch interlayer insulating layer 118b. In this case, the contact hole can be formed through the touch interlayer insulating layer 118b. The plurality of bridge electrodes BE is disposed below the touch interlayer insulating layer 118b to expose a part of the upper portions of the plurality of bridge electrodes BE by the contact hole.

The plurality of first layers L1 of the plurality of touch routing lines TL is disposed in the non-display area NA and can be formed of the same material on the same layer as the plurality of bridge electrodes BE.

Further, a plurality of auxiliary electrodes AE can be disposed on the plurality of touch buffer layers 118a so as to be spaced apart from the plurality of bridge electrodes BE and the plurality of first layers L1. The plurality of auxiliary electrodes AE can be disposed in the display area AA, and can be formed of the same material on the same layer as the plurality of bridge electrodes BE.

For example, each of the plurality of bridge electrodes BE, the plurality of auxiliary electrodes AE, and the plurality of first layers L1 can be formed of a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof, but is not limited thereto. For example, each of the plurality of bridge electrodes BE, the plurality of auxiliary electrodes AE, and the plurality of first layers L1 can have a three-layer structure of titanium (Ti), aluminum (Al), and titanium (Ti).

The touch interlayer insulating layer 118b is disposed on the touch buffer layer 118a so as to cover the plurality of bridge electrodes BE, the plurality of auxiliary electrodes AE, and the plurality of first layers L1, such that the plurality of bridge electrodes BE and the plurality of touch electrodes TE, the plurality of auxiliary electrodes AE and the plurality of touch electrodes TE, and the plurality of first layers L1 and the plurality of second layers L2 of the plurality of touch routing lines TL can insulate from each other.

The touch interlayer insulating layer 118b can be formed to extend to the non-display area NA as well as the display area AA. For example, the touch interlayer insulating layer 118b can be formed of an acrylic-based, epoxy-based, or siloxane-based organic material, but is not limited thereto.

For example, when a layer made of an inorganic material is applied as the touch interlayer insulating layer, it is difficult to form the thickness of the plurality of bridge electrodes to be greater than or equal to the thickness of the plurality of touch electrodes.

However, in the display device 100 according to the example embodiment of the present disclosure, the plurality of touch interlayer insulating layers 118b is formed of a layer made of an organic material to set the thickness of each of the plurality of bridge electrodes BE, the plurality of auxiliary electrodes AE, and the plurality of first layers L1 to be equal to or larger than the thickness of the plurality of touch electrodes TE and/or larger than the thickness of the plurality of the second layers L2.

A plurality of touch electrodes TE including a plurality of first touch electrodes TE1 and a plurality of second touch electrodes TE2 and a second layer L2 of the plurality of touch routing lines TL are disposed on the touch interlayer insulating layer 118b. The second layers L2 can be disposed on the same layer as the plurality of touch electrodes TE and alternately with the plurality of first layers L1.

The plurality of first touch electrodes TE1 can be disposed in the display area AA so as to overlap the plurality of bridge electrodes BE, and the plurality of first touch electrodes TE1 can be electrically connected to the plurality of bridge electrodes BE by contact holes present in the touch interlayer insulating layer 118b.

The plurality of second touch electrodes TE2 is disposed in the display area AA so as to overlap the plurality of auxiliary electrodes AE. The plurality of second touch electrodes TE2 can be electrically connected to the plurality of auxiliary electrodes AE disposed to overlap the plurality of second touch electrodes TE2 by a contact hole present in the touch interlayer insulating layer 118b. Since the plurality of auxiliary electrodes AE is electrically connected to the plurality of second touch electrodes TE2, the resistance of the touch sensing unit TS can be lowered. In this case, when the thickness of the plurality of auxiliary electrodes AE electrically connected to the plurality of second touch electrodes TE2 becomes larger than the thickness of the plurality of touch electrodes TE, the resistance of the touch sensing unit TS can be further lowered.

In the non-display area NA, the plurality of second layers L2 of the plurality of touch routing lines TL is disposed to at least partially overlap each of the plurality of first layers L1 of the plurality of touch routing lines TL. The plurality of first layers L1 and the plurality of second layers L2 can be electrically connected to each other by the contact hole present in the touch interlayer insulating layer 118b. For example, the plurality of touch routing lines TL can be a single alternating line in which the plurality of first layers L1 and the plurality of second layers L2 are alternately connected to each other.

The plurality of touch electrodes TE and the plurality of second layers L2 can each be formed of a single layer or a multi-layer formed of any one or more of molybdenum (Mo), copper (Cu), titanium (Ti), aluminum (Al), chromium (Cr), gold (Au), nickel (Ni), and neodymium (Nd) and an alloy thereof, but are not limited thereto. For example, each of the plurality of touch electrodes TE and the plurality of second layers L2 can have a three-layer structure of titanium (Ti), aluminum (Al), and titanium (Ti).

An organic layer can be further disposed to cover the plurality of touch electrodes TE and the plurality of second layers L2. For example, the organic layer can be formed of an organic material such as acryl resin, epoxy resin, phenolic resin, polyamide resin, and polyimide resin. The organic layer can prevent a step of the components of the display device 100 disposed below, thereby improving the visibility of the display device and protecting the components disposed therebelow.

In general, a touch routing line consisting of one layer was applied as a plurality of touch routing lines. However, a space according to a pitch of each of the plurality of touch routing lines is required between adjacent touch routing lines among the plurality of touch routing lines in consideration of a tolerance during a process. Accordingly, there is a problem in that a size of a bezel area in which the plurality of touch routing lines is disposed is increased.

In the display device 100 according to the example embodiment of the present disclosure, a single alternating line is applied as a plurality of touch routing lines TL, in which a plurality of first layers L1 and a plurality of second layers L2 positioned on different layers are alternately connected with each other.

Accordingly, among the plurality of touch routing lines TL, the plurality of first layers L1 and the plurality of second layers L2 of adjacent touch routing lines can be disposed to alternate with each other.

For example, adjacent touch routing lines TL is designed such that different layers, for example, the first layer L1 of one adjacent touch routing line TL and the second layer L2 of another adjacent touch routing line TL are disposed next to each other, so that the second layer L2 can be disposed between the spacing according to the pitch of the first layer L1. Accordingly, the distance between the plurality of touch routing lines TL can be reduced, and the size of the bezel area in which the plurality of touch routing lines TL is located can be reduced by approximately half.

In this case, unit lengths of the plurality of first layers L1 and the plurality of second layers L2 of the plurality of touch routing lines TL can be the same. Accordingly, it is possible to improve the process deviation when forming the plurality of first layers L1 and the plurality of second layers L2. For example, when unit lengths of the plurality of first layers and the plurality of second layers are different, a process deviation can occur. In this case, a length of each touch routing line can vary, and a resistance deviation can occur.

Further, in the display device 100 according to the example embodiment of the present disclosure, each of the plurality of first layers L1 and the plurality of second layers L2 can be formed in an even number. For example, when each of the plurality of first layers and the plurality of second layers is formed in odd numbers, there is a problem in that a resistance deviation occurs in a zigzag shape according to the process deviation, thereby deteriorating the touch performance. However, when each of the plurality of first layers L1 and the plurality of second layers L2 is formed to be an even number, the resistance is sequentially raised to the left and right of the channel so that the resistance change occurs linearly, thereby minimizing the occurrence of resistance deviation due to process deviation.

Meanwhile, when a single alternating line connecting a plurality of first layers and a plurality of second layers positioned on different layers as a plurality of touch routing lines alternately is applied, a distance between the plurality of touch routing lines can be reduced, but there can be a problem in that resistance of the plurality of touch routing lines increases.

Accordingly, in the display device 100 according to the example embodiment of the present disclosure, the plurality of auxiliary electrodes AE is electrically connected to the plurality of touch electrodes TE, for example, the plurality of second touch electrodes TE2 in the display area AA. Accordingly, the resistance of the touch sensing unit TS in the display area AA is lowered to compensate for the resistance of the plurality of touch routing lines TL electrically connected to the touch sensing unit TS.

In the display device 100 according to the example embodiment of the present disclosure, by applying a single alternating line as a plurality of touch routing lines, in which a plurality of first layers L1 and a plurality of second layers L2 positioned on different layers are alternately connected to each other, the distance between adjacent touch routing lines TL among the plurality of touch routing lines TL can be reduced, so that the size of the bezel area in which the plurality of touch routing lines TL is positioned can be reduced by approximately half.

Further, in the display device 100 according to the example embodiment of the present disclosure, the plurality of auxiliary electrodes AE is electrically connected to the plurality of second touch electrodes TE2 in the display area AA to improve the resistance of the touch sensing unit TS in the display area AA to compensate for the resistance of the plurality of touch routing lines TL electrically connected to the touch sensing unit TS.

Furthermore, in the display device 100 according to the example embodiment of the present disclosure, the unit length of the plurality of first layers L1 and the plurality of second layers L2 are adjusted and the number of the plurality of first layers L1 and the plurality of second layers L2 are adjusted to an even number, thereby improving the process deviation and minimizing the occurrence of the resistance deviation of the touch sensing unit TS.

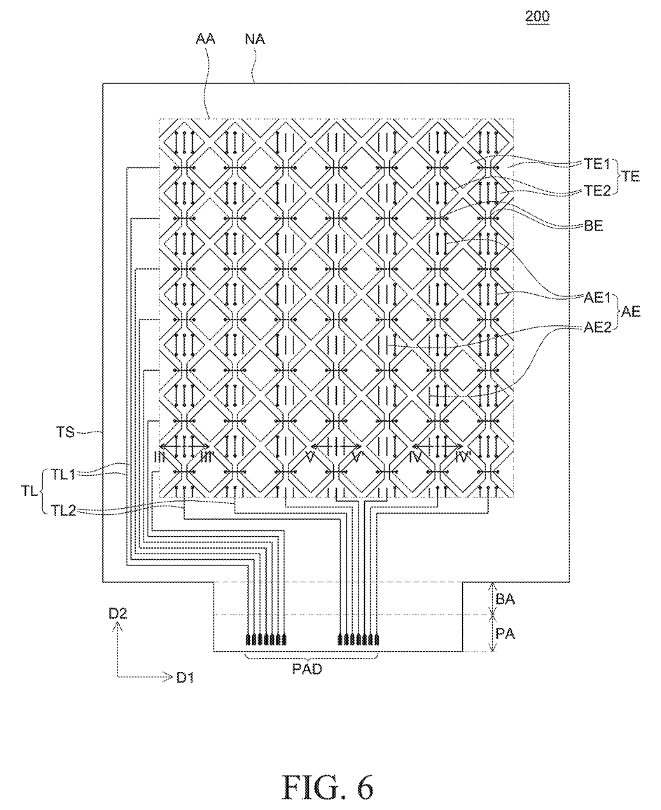

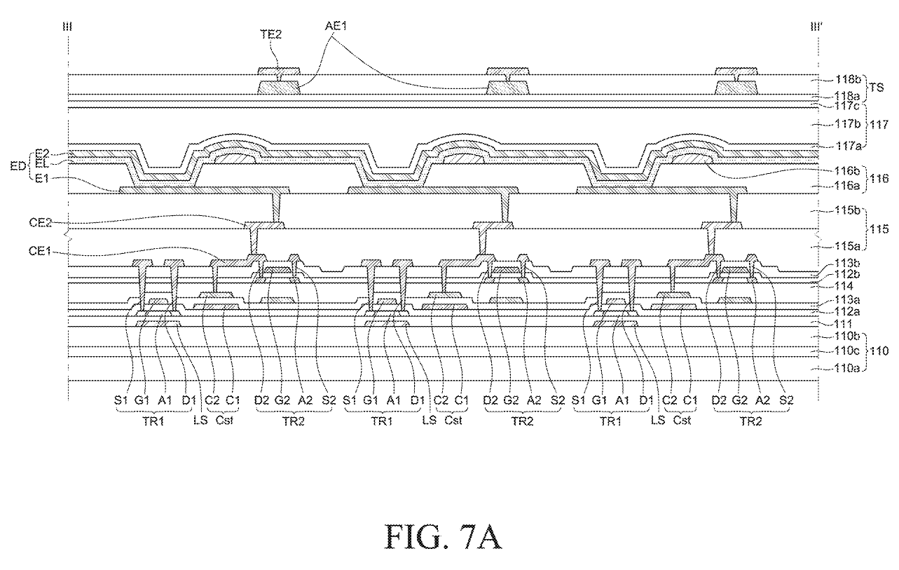

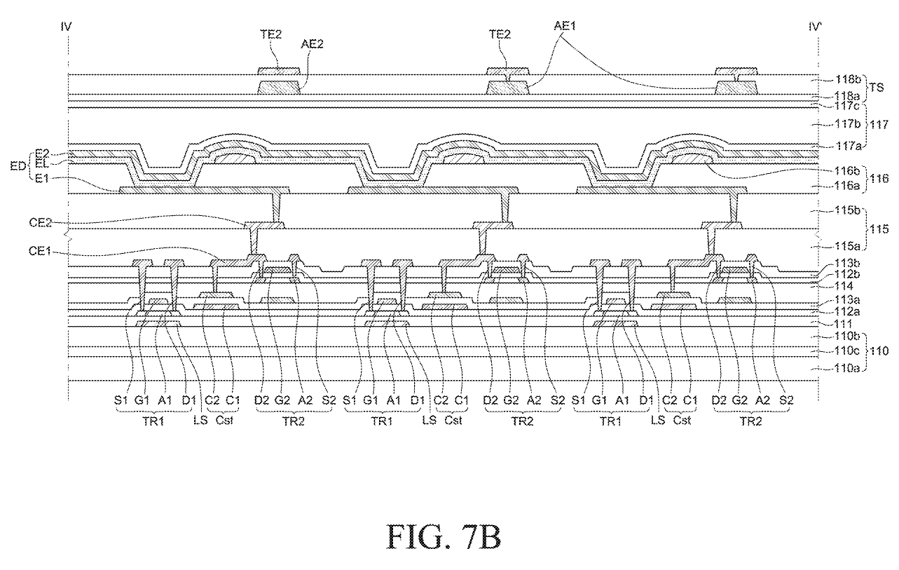

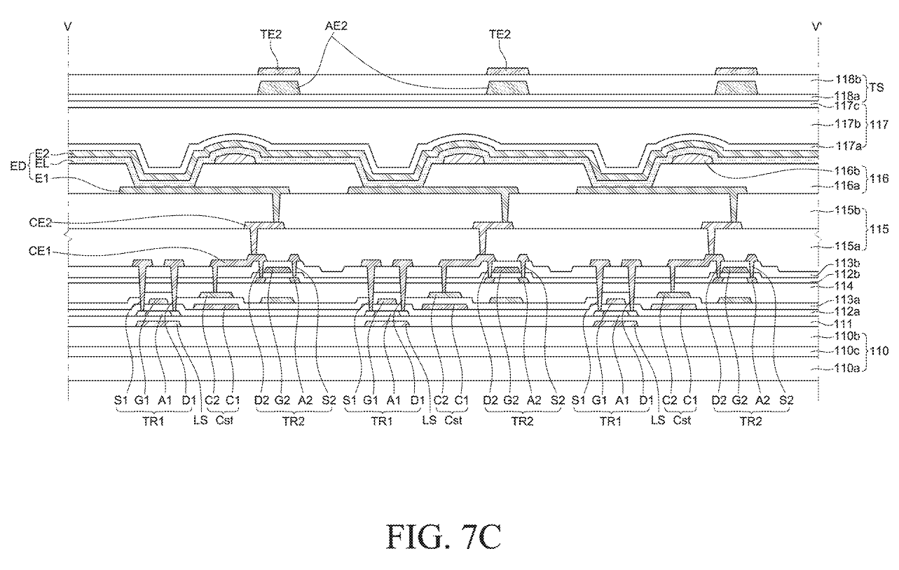

FIG. 6 is a plan view schematically illustrating a structure of a touch sensing unit according to another embodiment of the present disclosure. FIG. 7A is a cross-sectional view taken along the line III-III' of FIG. 6. FIG. 7B is a cross-sectional view taken along line IV-IV' in FIG. 6. FIG. 7C is a cross-sectional view taken along line V-V' in FIG. 6. The display device 200 of FIGS. 6-7C has substantially the same configuration as the display device 100 of FIGS. 1-5 except for a plurality of auxiliary electrodes. Therefore, for convenience of description, a redundant description other than a plurality of auxiliary electrodes will be omitted.

Referring to FIG. 6, in the display device 200 according to another example embodiment of the present disclosure, the plurality of second touch electrodes TE2 and the plurality of auxiliary electrodes AE overlapping each other can be electrically connected. At least some of the plurality of auxiliary electrodes AE overlapping the plurality of second touch electrodes TE2 can be electrically connected to the plurality of second touch electrodes TE2. For example, the plurality of auxiliary electrodes AE can include a plurality of first auxiliary electrodes AE1 electrically connected to the plurality of second touch electrodes TE2 and a plurality of second auxiliary electrodes AE2 insulated from the plurality of second touch electrodes TE2.

From the center toward the edge of the display area AA, the number of the plurality of auxiliary electrodes AE connected to each of the plurality of second touch electrodes TE2 for example, the number of the plurality of first auxiliary electrodes AE1 can increase, and the number of the plurality of auxiliary electrodes AE insulated from each of the plurality of second touch electrodes TE2, that is the number of the plurality of second auxiliary electrodes AE2 can decrease.

In general, the lengths of the plurality of touch routing lines are changed according to the positions of the plurality of touch routing lines, and accordingly, resistance deviation and RC deviation between the plurality of touch routing lines can occur.

Accordingly, in the display device 200 according to another example embodiment of the present disclosure, the number of the plurality of auxiliary electrodes AE connected to the plurality of second touch electrodes TE2 is changed according to the positions of the plurality of second touch electrodes TE2 electrically connected to the plurality of touch routing lines TL, thereby improving the resistance deviation and RC deviation according to the positions of the plurality of touch routing lines TL.

For example, in the edge of the display area AA, as the plurality of touch routing lines TL is formed to be relatively long, resistance and RC delay increase. Accordingly, as illustrated in FIG. 7A, the plurality of first auxiliary electrodes AE1 and the plurality of second touch electrodes TE2 are electrically connected at the edge of the display area AA to compensate for the resistance of the touch sensing unit TS and reduce the RC delay to compensate for the resistance and RC delay generated in the plurality of touch routing lines TL. Further, in the center portion of the display area AA, the plurality of touch routing lines TL is formed to be relatively short, such that a resistance is formed to be small. Accordingly, as shown in FIG. 7C, the plurality of second auxiliary electrodes AE2 insulated from the plurality of second touch electrodes TE2 is disposed in the center of the display area AA to maintain the RC delay without compensating for the resistance in the display area AA. In addition, as illustrated in FIG. 7B, in the area between the center portion and the edge of the display area AA, the plurality of first auxiliary electrodes AE1 and the plurality of second auxiliary electrodes AE2 are disposed together in the display area AA to compensate for a part of the resistance generated by the plurality of touch routing lines TL, and the RC delay can be lowered. Accordingly, the resistance and RC delay deviation according to the positions of the plurality of touch routing lines TL are compensated in the display area AA to improve the resistance deviation and RC deviation of the plurality of touch routing lines TL.

In this case, among the plurality of second touch electrodes TE2 and the plurality of auxiliary electrodes AE, the number of the plurality of auxiliary electrodes AE electrically connected to each of the plurality of second touch electrodes TE2 positioned along the same line in the second direction D2 from the bottom to the top of the display area AA can be the same.

Meanwhile, the plurality of second auxiliary electrodes AE2 can be disposed on the same layer as the plurality of bridge electrodes BE while being insulated from the plurality of second touch electrodes TE2. For example, when the plurality of second auxiliary electrodes AE2 is deleted, an area from which the plurality of second auxiliary electrodes AE2 is deleted can change patterns of an area in which the plurality of first auxiliary electrodes AE1 and the plurality of bridge electrodes BE are disposed, and accordingly, the changed pattern can be visually recognized by the user. Accordingly, when the plurality of second auxiliary electrodes AE2 remains insulated from the plurality of second touch electrodes TE2, visibility can be improved because it is perceived as the same pattern by the user. However, the present disclosure is not limited thereto, and the plurality of second auxiliary electrodes AE2 can be deleted.

The example embodiments of the present disclosure can also be described as follows:

According to an aspect of the present disclosure, a display device includes a substrate including a display area in which a plurality of sub pixels are disposed and a non-display area disposed to surround the display area and including a bending area and a pad area, a plurality of light emitting elements disposed in the plurality of sub pixels, an encapsulation part disposed to cover the plurality of light emitting elements, a touch sensing unit including a plurality of bridge electrodes disposed on the encapsulation part and a plurality of touch electrodes disposed on or below the plurality of bridge electrodes, a plurality of pads disposed in the pad area, and a plurality of touch routing lines disposed in the non-display area and electrically connecting the plurality of touch electrodes and the plurality of pads, the plurality of touch routing lines includes a plurality of first layers disposed on the same layer as the plurality of bridge electrodes, and a plurality of second layers disposed on the same layer as the plurality of touch electrodes and alternately with the plurality of first layers.

According to the example embodiments of the present disclosure, the display device can further include a plurality of auxiliary electrodes which is disposed on the same layer as the plurality of bridge electrodes in the display area and is disposed to overlap the plurality of touch electrodes.

According to an example embodiments of the present disclosure, the plurality of touch electrodes includes a plurality of first touch electrodes disposed in a first direction and a plurality of second touch electrodes disposed in a second direction intersecting the first direction, and the plurality of auxiliary electrodes can overlap the plurality of second touch electrodes.

According to the example embodiments of the present disclosure, the plurality of second touch electrodes and the plurality of auxiliary electrodes overlapping each other can be electrically connected.

According to the example embodiments of the present disclosure, at least some of the plurality of auxiliary electrodes overlapping the plurality of second touch electrodes can be electrically connected to the plurality of second touch electrodes, and the number of the plurality of auxiliary electrodes connected to each of the plurality of second touch electrodes can increase from the center portion of the display area to the edge of the display area.

According to the example embodiments of the present disclosure, among the plurality of second touch electrodes and the plurality of auxiliary electrodes, the number of the plurality of auxiliary electrodes connected to each of the plurality of second touch electrodes positioned along the same line from the bottom to the top of the display area can be the same.

According to the example embodiments of the present disclosure, the display device can further including a touch interlayer insulating layer disposed between the plurality of bridge electrodes and the plurality of touch electrodes, the touch interlayer insulating layer can be formed of an organic material, and the plurality of bridge electrodes, the plurality of auxiliary electrodes, and the plurality of first layers can have thicknesses greater than those of each of the plurality of touch electrodes and the plurality of second layers, respectively.

According to an example embodiments of the present disclosure, each of the plurality of first layers and the plurality of second layers can be an even number.

According to an example embodiments of the present disclosure, in a plurality of touch routing lines adjacent to each other among the plurality of touch routing lines, a plurality of first layers and a plurality of second layers can be alternately disposed.

According to an aspect of the present disclosure, a display device includes a substrate which includes a display area in which a plurality of sub pixels are disposed and a non-display area disposed to surround the display area and including a bending area and a pad area, a plurality of light emitting elements disposed in the plurality of sub pixels, an encapsulation part disposed to cover the plurality of light emitting elements, a touch sensing unit including a plurality of bridge electrodes disposed on the encapsulation part, a touch interlayer insulating layer covering the plurality of bridge electrodes, a plurality of first touch electrodes disposed on the touch interlayer insulating layer and disposed in a first direction, and a plurality of second touch electrodes disposed in a second direction intersecting the first direction, a plurality of pads disposed in the pad area, a plurality of first touch routing lines electrically connecting the plurality of first touch electrodes and the plurality of pads in the non-display area, and a plurality of second touch routing lines electrically connecting the plurality of second touch electrodes and the plurality of pads, wherein the plurality of second touch routing lines includes a first layer disposed on the same layer as the bridge electrode and a second layer disposed on the same layer as the plurality of first touch electrodes and the plurality of second touch electrodes, and the first layer and the second layer are disposed alternately with each other.

According to another example embodiment of the present disclosure, the display device can further include a plurality of auxiliary electrodes which is disposed on the same layer as the plurality of bridge electrodes in the display area and is disposed in the second direction so as to overlap the plurality of second touch electrodes, and the bridge electrode can electrically connect the plurality of first touch electrodes.

According to another example embodiment of the present disclosure, a plurality of second touch electrodes and a plurality of auxiliary electrodes overlapping each other can be electrically connected.

According to another example embodiment of the present disclosure, the plurality of auxiliary electrodes can include a plurality of first auxiliary electrodes electrically connected to the plurality of second touch electrodes, and a plurality of second auxiliary electrodes electrically insulated from the plurality of second touch electrodes, and from a center portion of the display area to an edge of the display area, the number of the plurality of first auxiliary electrodes can increase and the number of the plurality of second auxiliary electrodes can decrease.

According to another example embodiment of the present disclosure, among the plurality of second touch electrodes and the plurality of auxiliary electrodes, the number of the plurality of first auxiliary electrodes and the plurality of second auxiliary electrodes positioned along the same line in the second direction can be the same.

According to another example embodiment of the present disclosure, each of the plurality of first layers and the plurality of second layers can be an even number.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a display area in which a plurality of sub pixels are disposed and a non-display area around the display area, the non-display area including a bending area and a pad area;
a plurality of light emitting elements disposed in the plurality of sub pixels;
an encapsulation part disposed to cover the plurality of light emitting elements;
a touch sensing unit including a plurality of bridge electrodes disposed on the encapsulation part and a plurality of touch electrodes disposed on or below the plurality of bridge electrodes;
a plurality of pads disposed in the pad area; and
a plurality of touch routing lines disposed in the non-display area and electrically connecting the plurality of touch electrodes and the plurality of pads,
wherein the plurality of touch routing lines includes:
a plurality of first layers disposed on a same layer as the plurality of bridge electrodes; and
a plurality of second layers disposed on a same layer as the plurality of touch electrodes and alternately with the plurality of first layers.

2. The display device according to claim 1, further comprising:
a plurality of auxiliary electrodes disposed on a same layer as the plurality of bridge electrodes in the display area, and disposed to overlap the plurality of touch electrodes.

3. The display device according to claim 2, wherein the plurality of touch electrodes includes a plurality of first touch electrodes disposed in a first direction and a plurality of second touch electrodes disposed in a second direction intersecting the first direction, and
wherein the plurality of auxiliary electrodes overlaps the plurality of second touch electrodes.

4. The display device according to claim 3, wherein the plurality of second touch electrodes and the plurality of auxiliary electrodes overlapping each other are electrically connected.

5. The display device according to claim 3, wherein at least some of the plurality of auxiliary electrodes overlapping the plurality of second touch electrodes are electrically connected to the plurality of second touch electrodes and
wherein a number of the plurality of auxiliary electrodes connected to one of the plurality of second touch electrodes increases from a center portion of the display area to an edge of the display area.

6. The display device according to claim 5, wherein among the plurality of second touch electrodes and the plurality of auxiliary electrodes, the number of the plurality of auxiliary electrodes connected to one of the plurality of second touch electrodes positioned along a same line from a bottom to a top of the display area is the same.

7. The display device according to claim 2, further comprising:
a touch interlayer insulating layer disposed between the plurality of bridge electrodes and the plurality of touch electrodes,
wherein the touch interlayer insulating layer includes an organic material, and
wherein the plurality of bridge electrodes, the plurality of auxiliary electrodes, and the plurality of first layers have thicknesses greater than those of the plurality of touch electrodes and the plurality of second layers, respectively.

8. The display device according to claim 1, wherein the plurality of first layers and the plurality of second layers include respectively an even number of layers.

9. The display device according to claim 1, wherein in a plurality of touch routing lines adjacent to each other among the plurality of touch routing lines, the plurality of first layers and the plurality of second layers are alternately disposed.

10. The display device according to claim 1, wherein unit lengths of the plurality of first layers and the plurality of second layers of the plurality of touch routing lines are the same.

11. The display device according to claim 3, wherein the plurality of auxiliary electrodes includes:
a plurality of first auxiliary electrodes electrically connected to the plurality of second touch electrodes; and
a plurality of second auxiliary electrodes electrically insulated from the plurality of second touch electrodes.

12. The display device according to claim 11, wherein from a center portion of the display area to an edge of the display area, a number of the plurality of first auxiliary electrodes increases, and a number of the plurality of second auxiliary electrodes decreases.

13. The display device according to claim 1, wherein some first layers among the plurality of first layers and some second layers among the plurality of second layers are positioned on different layers and are alternately connected with each other.

14. The display device according to claim 1, wherein the touch sensing unit further includes a touch buffer layer disposed on the encapsulation part, and
wherein the plurality of bridge electrodes and the plurality of first layers of the plurality of touch routing lines are disposed on the touch buffer layer.

15. A display device comprising:
a substrate including a display area in which a plurality of sub pixels are disposed and a non-display area around the display area, the non-display area including a bending area and a pad area;
a plurality of light emitting elements disposed in the plurality of sub pixels;
an encapsulation part disposed to cover the plurality of light emitting elements;
a touch sensing unit including a plurality of bridge electrodes disposed on the encapsulation part, a touch interlayer insulating layer covering the plurality of bridge electrodes, a plurality of first touch electrodes disposed on the touch interlayer insulating layer and disposed in a first direction, and a plurality of second touch electrodes disposed in a second direction intersecting the first direction;
a plurality of pads disposed in the pad area;
a plurality of first touch routing lines electrically connecting the plurality of first touch electrodes and the plurality of pads in the non-display area; and
a plurality of second touch routing lines electrically connecting the plurality of second touch electrodes and the plurality of pads,
wherein the plurality of second touch routing lines includes at least one first layer disposed on a same layer as one of the plurality of bridge electrodes, and at least one second layer disposed on a same layer as the plurality of first touch electrodes and the plurality of second touch electrodes, and
wherein the at least one first layer and the at least one second layer are disposed alternately with each other.

16. The display device according to claim 15, further comprising:
a plurality of auxiliary electrodes disposed on a same layer as the plurality of bridge electrodes in the display area and disposed in the second direction so as to overlap the plurality of second touch electrodes,
wherein one of the plurality of bridge electrodes electrically connects the plurality of first touch electrodes.

17. The display device according to claim 16, wherein the plurality of second touch electrodes and the plurality of auxiliary electrodes overlapping each other are electrically connected.

18. The display device according to claim 16, wherein the plurality of auxiliary electrodes includes:
a plurality of first auxiliary electrodes electrically connected to the plurality of second touch electrodes; and
a plurality of second auxiliary electrodes electrically insulated from the plurality of second touch electrodes,
wherein, from a center portion of the display area to an edge of the display area, a number of the plurality of first auxiliary electrodes increases, and a number of the plurality of second auxiliary electrodes decreases.

19. The display device according to claim 18, wherein among the plurality of second touch electrodes and the plurality of auxiliary electrodes, the number of the plurality of first auxiliary electrodes and the plurality of second auxiliary electrodes positioned along a same line in the second direction is the same.

20. The display device according to claim 15, wherein the at least one first layer includes an even number of first layers and the at least one second layer includes an even number of second layers.

21. The display device according to claim 15, wherein the touch sensing unit further includes a touch buffer layer disposed on the encapsulation part, and
wherein the plurality of bridge electrodes and the at least one first layer of the plurality of second touch routing lines are disposed on the touch buffer layer.

22. The display device according to claim 16, wherein the touch interlayer insulating layer includes an organic material to set a thickness of each of the plurality of bridge electrodes, the plurality of auxiliary electrodes, and the at least one first layer to be equal to or larger than a thickness of the plurality of first touch electrodes or the plurality of second touch electrodes.

23. The display device according to claim 15, wherein unit lengths of the at least one first layer and the at least one second layer of the plurality of second touch routing lines are the same.
